(19) United States
(12) Patent Application Publication
(10) Pub. No.: US 2026/0213982 A1
(43) Pub. Date: Jul. 23, 2026

(54) REDUCING CROSS-TALK AMONG SIGNALS

(71) Applicant: Shaoxing Yuanfang Semiconductor Co., Ltd., Shaoxing (CN)

(72) Inventors: Madhusudan Srinivasan, Bangalore (IN); Raja Prabhu J, Bangalore (IN); Harshit Rathore, Bangalore (IN); Laxmi Choudhary, Bangalore (IN); Kranthi Kadiyala, Bangalore (IN)

(21) Appl. No.: 19/361,037

(22) Filed: Oct. 17, 2025

(30) Foreign Application Priority Data
Jan. 22, 2025 (IN) 202541005303

(51) Int. Cl. H04L 25/02; H04B 1/04; H04B 1/16; H04B 1/18

(52) U.S. Cl. CPC H04L 25/0296; H04B 1/04; H04B 1/1607; H04B 1/18; H04L 25/0272; H04L 25/0278

(57) ABSTRACT

A circuit contains multiple signal traces, multiple transmitters and multiple receivers. Each of the multiple signal traces has an input end and an output end, and propagates a corresponding input signal received at its input end to its output end. Each of the multiple transmitters is connected to a corresponding input end of a respective signal trace. Each of the multiple receivers is connected to a corresponding output end of a respective signal trace. Each receiver contains a self-biased inverter biased in a high-gain region. The DC operating-point of each driver equals that of the corresponding receiver.

### PRIORITY CLAIM

The instant patent application is related to and claims priority from the co-pending India provisional patent application entitled, “Low Noise/Cross-Talk Output Clock Distribution”, Serial No.: 202541005303, Filed: 22Jan. 2025, Attorney docket no.: AURA- 370-INPR, which is incorporated in its entirety herewith to the extent not inconsistent with the description herein.

### RELATED APPLICATION

The present application is related to the co-pending application Entitled, “Multiplexer to Connect any of Multiple Input Signals to an Output Path” , Serial Number: UNASSIGNED, filed on even date herewith, attorney docket number: AURA-078-US, naming the same inventors as in the present application, and which is incorporated in its entirety herewith to the extent not inconsistent with the description herein.

### BACKGROUND

### Technical Field

Embodiments of the present disclosure relate generally to signal transmission in wireline media, and more specifically to reducing cross-talk among such transmitted signals.

### Related Art

There are often situations where there are multiple signals which are required to be transmitted via wires (signal traces) that lie in close proximity. For example, in systems such as complex Systems-on-Chip (SOC), network devices, wireline transceivers, etc., there is a need to generate and/or transmit multiple signals (of different frequencies on respective input ports) on wires, with each signal potentially being required to be made available at any of multiple output ports (e.g., located at package pins of a SOC).

The signal traces between the transmitting ends and the receiving ends are in close proximity, potentially leading to cross-talk of sufficient magnitude to cause signal degradation/corruption, etc., as is well known in the relevant arts. A similar problem may exist when multiple signals are routed in close proximity over point-to-point (non-switchable) connections too.

Aspects of the present disclosure are directed to reducing cross-talk among such transmitted signals.

### BRIEF DESCRIPTION OF THE VIEWS OF DRAWINGS

Example embodiments of the present disclosure will be described with reference to the accompanying drawings briefly described below.

FIG. 1 is a block diagram of an example device in which several aspects of the present disclosure can be implemented.

FIG. 2 is a diagram illustrating a layout of multiple signal paths that need to be present to connect multiple start-points selectively to multiple end-points, in an embodiment of the present disclosure.

FIG. 3 is a diagram illustrating the components in a path from a source of a signal to an end-point of the signal in a device, in an embodiment of the present disclosure.

FIG. 4A is a diagram illustrating the implementation details of a self-biased inverter in an embodiment of the present disclosure.

FIG. 4B is a diagram showing the output-input relation of a self-biased inverter in an embodiment of the present disclosure.

FIG. 5 is a diagram used to illustrate impedance matching.

FIG. 6A is a diagram depicting waveforms illustrating the manner in which phase noise in a clock signal is prevented/reduced by employing a back-to-back connected pair of inverters.

FIG. 6B is a diagram depicting waveforms illustrating the manner in which a back-to-back connected pair of inverters prevents/minimizes cross-talk.

FIG. 7 is a block diagram of a transmitter illustrating the manner in which the drive strength is controlled in an embodiment.

FIG. 8 is a block diagram illustrating the details of a system in an embodiment of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

A circuit provided according to an aspect of the present disclosure contains signal traces having an input end and an output end, with each signal trace to propagate a corresponding input signal received at the corresponding input end to the corresponding output end. The circuit also contains multiple drivers, with each driver being coupled to a corresponding input end of a respective signal trace. Receivers are coupled to respective output ends of the signal traces. According to aspect, each receiver contains a self-biased inverter biased in a high-gain region, wherein a DC operating-point of each driver equals that of the corresponding receiver.

By having the same DC operating-point, in combination with a self-biased inverter biased in a high-gain region, intermediate components such as coupling capacitors may be avoided, thereby providing several benefits. The benefits can include absence of lower-limit for frequency of (clock) signals, reduced signal decay, lesser implementation area, etc.

In an embodiment, the signal traces are contained in a signal distributor operable to connect any input port to any output port, with each signal trace being constituted on one path from an input port to the corresponding output port.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Example Device

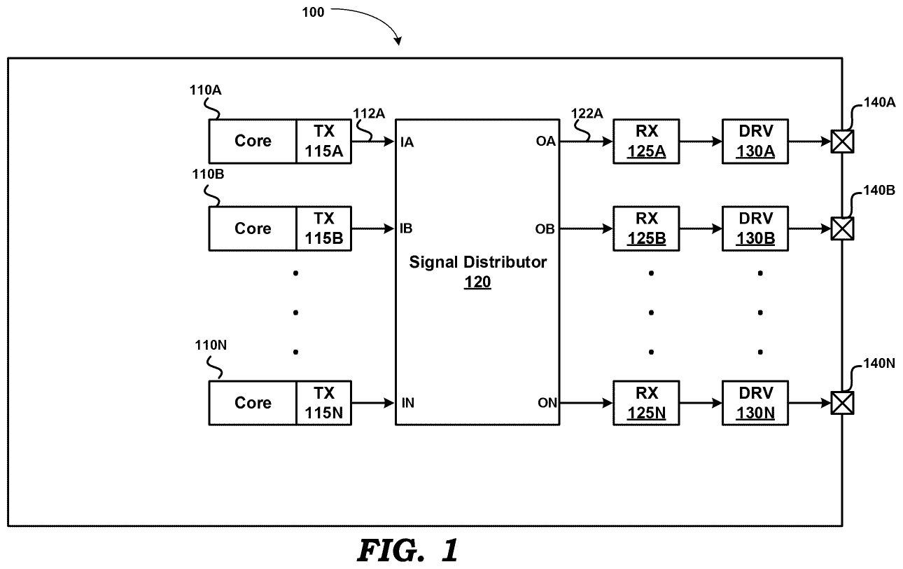

FIG. 1 is a block diagram of an example device in which several aspects of the present disclosure can be implemented. FIG. 1 shows relevant portions of an integrated circuit (IC) 100 (which may be a SOC), which is in turn shown containing signal generators 110A through 110N, signal distributor 120, receivers (Rx) 125A through 125N, output drivers (DRV) 130A through 130N and pins 140A through 140N. IC 100 may be viewed as a ‘clock IC’.

According to the convention used herein, signal generators 110A through 110N are collectively or individually referred by reference numeral 110, as will be clear from the context. Similar convention is used for other similar components as well. Other portions of IC 100 such as power supplies, oscillators, etc., are not shown in FIG. 1 in the interest of clarity and conciseness. Further, the specific blocks of FIG. 1 are shown merely by way of example. Various aspects of the present disclosure can be implemented in other devices and environments too.

In the example of FIG. 1, each of signal generators 110A through 110N is a phase locked loop (PLL) and generates clock signals. The clock signals described herein can have frequencies ranging from a few Hertz (Hz) to several giga Hertz (GHz). The clocks can have a waveform of square waves (or non-sinusoidal waves, in general), sinusoidal waves, etc., although the description provided herein assumes square waves.

While the following description is provided with respect to clock signals, it may be appreciated that features of the present disclosure are applicable to other types of signals such as information-bearing (modulated) signals such as, for example, video signals, sinusoidal RF local-oscillator signals used in wireless equipment, etc. In general, the nature of the signals and their routing (signal traces and their layout/proximity) from generator to receiver (or other end-point in general) is such that they potentially present the problem of cross-talk. Further, each of the paths from a transmitter/driver to a pin of IC 100 is described herein as a differential path carrying differential signals. However, such paths and signals can also be single-ended signals with corresponding modifications to the circuits and blocks described herein, as would be apparent to one skilled in the relevant arts upon reading the disclosure herein.

Furthermore, the description below is provided in the context of signals that pass through a signal distributor that can selectively forward a signal from any of its input ports to any one of its output ports. It is noted here that when such flexible signal distribution is needed, the problem of cross-talk may be worse when such a flexible signal distribution capability exists due to the need for a large number of signal traces and connections to and from the traces (and the resulting trace-routing congestion), than if a straightforward fixed one-to-one connection is sufficient between a signal generator and an output pin of IC 100 (via a receiver), but without having to pass through a signal distributor. However, it is to be understood that various aspects of the present disclosure are equally applicable to such simpler fixed one-to-one connections also, i.e., in the absence of a signal distributor.

As noted above, each of signal generators 110A-110N is a PLL. In addition to the PLL circuitry (not shown in FIG. 1, but noted as ‘Core’ in each of the signal generators 110), each signal generator (110) is also shown containing a transmitter (or driver), respectively numbered 115A through 115N (and generically referred to herein as driver 115). The core in each PLL 110A-110N generates a respective clock signal (clock) that is synchronized to a corresponding reference clock (not shown). In an embodiment, the internal blocks (phase detector, low-pass filter, etc.) in each PLL are single-ended circuits, and the generated clock signals are single-ended signals. However, in an alternative embodiment, IC 100 employs fully-differential PLLs that generate differential clock signals. When the PLL circuitry generates a single-ended clock signal, a single-ended to differential converter circuit is used to convert the single-ended clock signal to differential form. In the embodiments described herein, all of the transmitters, signal distributor 120, receivers and drivers employ differential circuits and operate on differential signals. However, in an alternative embodiment, all the components and blocks of FIG. 1 are single-ended circuits.

Each transmitter (Tx) 115 of a signal generator receives the clock signal from the corresponding core of a signal generator 110 and forwards the clock signal with the necessary drive strength to a corresponding input port of signal distributor 120. For example, Tx 115A receives the clock signal generated by the core (i.e., PLL circuitry) in PLL 110A, and drives the clock on to input port I1 of signal distributor 120. As is well known in the relevant arts, the required drive strength may be determined from the characteristics of (impedances associated with) the path from the transmitter to an end-point such as a corresponding receiver (one of Rx 125A-Rx 125N).

A transmitter 115 is implemented to have an output impedance (source termination) that has a value that is selected relative to the characteristic impedance of the path from the transmitter to the corresponding receiver to minimize signal distortion as well as cross-talk, as described further below. Each of transmitters 115 is controllable to drive a clock signal with an amplitude (signal-swing) that may be large enough to be reliably received at a corresponding receiver, but small enough to reduce cross-talk between/among the multiple clock signals. In an embodiment, the frequency of clocks signals generated by the signal generators 110 ranges from 1 Hz to several GHz.

Signal distributor 120 has multiple input ports (IA through IN) and multiple output ports (OA-ON). Signal distributor 120 receives a corresponding clock signal as input on each of its input ports. To illustrate, in FIG. 1 signal distributor 120 is shown as receiving clock signal 112A from Tx 115A on input port IA. Signal distributor 120 is designed to selectively connect an input port to any (one) of the output ports. The selection can be made by generating respective control signals which are not shown in FIG. 1, but can be generated as external input to IC 100, from a non-volatile memory unit storing configuration data within IC 100 or other known techniques. Each of the input ports can be connected to any one of the output ports.

Signal distributor 120 may be implemented to provide such connections between input and output ports using techniques designed to minimize routing congestion, and thereby crosstalk, between or among clock signals on the connecting routes/signal-traces/paths within it. Some example implementations of signal distributor 120 are cross-point switch matrix and analog multiplexers. A connecting trace between a transmitter 115, through signal distributor 120 and to a receiver 125 is implemented to provide a controlled impedance. The connecting paths can be implemented in a known way, such as for example, as strip-lines.

Each of receivers (Rx) 125A-125N is connected to a corresponding one of the output ports of signal distributor 120. To illustrate, Rx 125A is shown connected to output port O1. Receivers 125 receive a corresponding clock signal from an output port and amplify the clock signal to a desired level. For example, when the clocks are square-wave signals with binary logic levels, receivers 125 may be designed to amplify the received clock signals to rail-to-rail levels. The received clock signals may have low signal-swing levels (low amplitude) either due to having been generated as low signal-swing signals and/or may have been distorted by noise and/or signal reflections, as further described below. Receivers 125 forward the respective amplified signals (after internal buffering) to a corresponding output driver in output drivers 130. To illustrate, Rx 125A is shown connected to output driver 130A of drivers 130.

Output drivers (DRV) 130 contain multiple drivers 130A-130N, which respectively receive a respective amplified-and-buffered clock signal and drive the amplified-and-buffered clock signal with the desired strength to corresponding output pins 140 of IC 100. In an embodiment, the number of signal generators 110 equals the number of output pins 140. However, in some alternative embodiments, the number of signal generators can be smaller than the number of output pins 140.

In an embodiment, each of transmitters 115, signal distributor 120, receivers 125 and output drivers 130 is implemented to handle differential signals, and pins 140 are each a pair of differential output pins. In an alternative embodiment, transmitters 115, signal distributor 120, receivers 125 and output drivers 130 are implemented to handle single-ended signals.

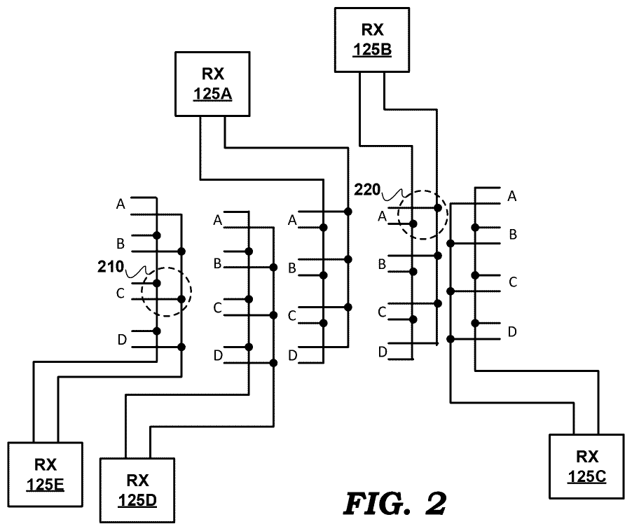

FIG. 2 shows a portion of an example layout of the multiple signal traces from transmitters Tx 115 to receivers Rx 125 via signal distributor 120. The portion shows signal traces needed between four signal generators 110A-110D (respectively labelled A, B, C and D in the Figure) and five receivers 125A-125E. The path from a signal generator to a receiver can be controllably connected at a corresponding junction (e.g., junctions 210 and 220) by applying a control signal at signal distributor 120. The requirement to provide each signal generator's (110) clock at any one of the output pins 140 of IC 100, a large number of interconnecting paths or signal traces may need to be provided. The paths/traces may need to be spaced physically close in IC 100 (e.g., within signal distributor 120 as well as leading to and out of it) due to space constraints making the clock signals on such paths susceptible to cross-talk, more so as the number of signal generators and receivers increases. Techniques for reducing cross-talk in such scenarios are described next.

### 3. Transmitter and Receiver

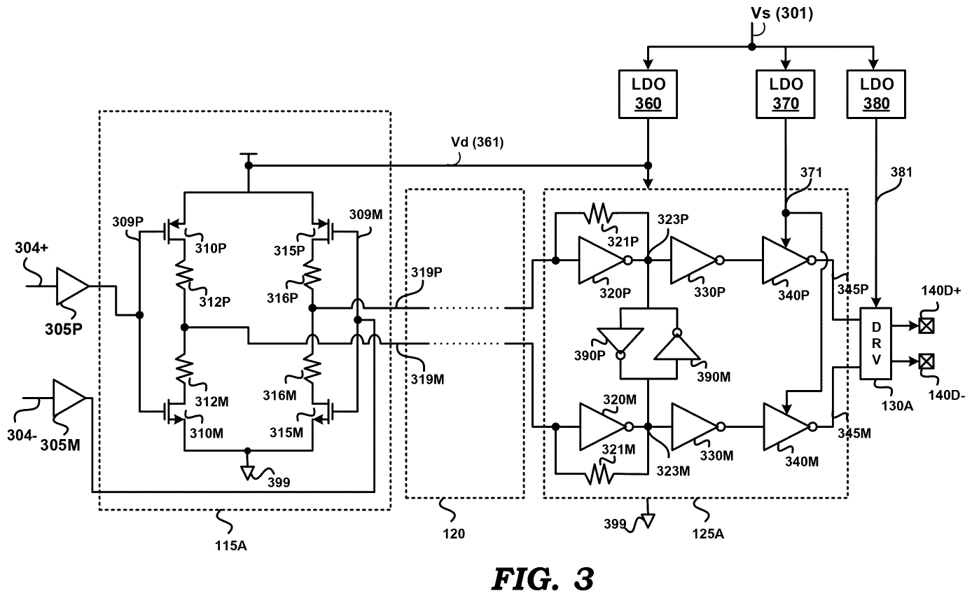

FIG. 3 is a diagram illustrating the circuits and components in a path from a source of a clock signal to an end-point of the signal in IC 100 (output pins of the IC in the example), in an embodiment of the present disclosure. The signal path in FIG. 3 starts at the output (304+/304−) of the core (PLL circuitry) in clock generator 110A, passes through transmitter 115A, signal distributor 120, receiver 125A, driver 130A in output drivers (DRV) 130, and ends at IC pins 140D+/140D−. For simplicity and ease of description, the output of transmitter 115A is shown as being connected via the corresponding path(s) in signal distributor 120 to receiver 125A. However, in general, the clock signal at the output of any of the transmitters 115 can be connected to any of the receivers 125 by appropriate control of signal distributor 120.

More specifically, FIG. 3 shows the implementation of a clock transmitter (or driver) and a clock receiver in IC 100. Transmitter 115A is shown there connected to a pair of IC pins 140+/140− via receiver 125A and (driver 130A of) output driver 130. A single-ended to differential converter (not shown) in signal generator 110A converts the single-ended clock output of PLL 110A to differential form across paths 304+and 304−. Buffers 305P and 305M buffer the differential clock signal, which is then applied to respective portions of differential transmitter 115A at respective nodes 309P and 309M. Differential transmitter 115A is powered by a supply voltage 361 (Vd). Terminal 399 represents a ground terminal. All the other transmitters and receivers of FIG. 1 are implemented identical or similar to transmitter 115A and receiver 125A respectively.

Differential transmitter 115A is shown containing a (symmetrical) pair of circuit portions, one each for receiving and transmitting a respective one of a pair of complementary signals of a differential signal across the outputs of buffers 305P and 305M. A first portion is shown containing P-channel metal oxide semiconductor field effect transistor (PMOS) 310P, N-channel metal oxide semiconductor field effect transistor (NMOS) 310M, and resistors R1 (312P) and R2 (312M). The other portion is shown containing PMOS 315P, NMOS 315M, and resistors R3 (316P) and R4 (316M). The resistances of resistors R1, R2, R3 and R4 are all designed to be equal (R). Differential transmitter 115A is shown powered by a supply voltage Vd (361).

Transmitter 115A represents a source-series terminated (SST) differential inverter. The differential output impedance of transmitter 115A equals 2 R ohms. In an embodiment, the differential output impedance (2 R) (with R being approximately 100 ohms) of transmitter 115A (i.e., the source-series termination (SST) value) is implemented to be less than the characteristic impedance (Zo) of the transmission path/channel from transmitter 115A to receiver 125A (and through the corresponding path in signal distributor 120), and is selectable among one of several values as described in sections below. In an embodiment, the SST is set to be equal to Zo/2. As is well known in the relevant arts, the characteristic impedance of a differential trace is the instantaneous impedance of the pair of traces as seen by a differential signal on the differential trace, and is determined by the physical and electrical parameters of both the traces and their environment. In general, a small value for the SST (also termed as source impedance Zs herein) ensures that rise and fall times of the transmitted clock signal are short which makes the clock signal more immune to any noise injection.

In operation, when the voltages at nodes 309P and 309M respectively correspond to logic high and logic low, the voltages at nodes/paths 319P and 309M also respectively correspond to logic high and logic low. When the voltages at nodes 309P and 309M respectively correspond to logic low and logic high, the voltages at nodes/paths 319P and 309M also respectively correspond to logic low and logic high. The voltage swing on each of terminals 319P and 319M is adjustable, as described in sections below. In an embodiment, the voltage swing across 319P/319M is made small (e.g., +/−700 milli Volts (mV)) to minimize cross-talk, with supply voltage Vd (361) set to 1.4V. The voltage at nodes 319P and 319M are determined by the feedback resistor (resistors 321P and 321M) at the receiver, the series resistor at the transmitter (312P, 312M, 316P and 316M) and the ON-resistance of the corresponding NMOS/PMOS transistors.

When the logic level across 319P and 319M is a logic high (positive voltage between nodes 319P and 319M), the voltages at nodes 319P and 319M are expressed by the following equations:

$$V 319 P = VDD * [ ( Rrx + Ron\_rx \_nmos ) / ( Rrx + Ron\_rx \_nmos + Rtx + Ron\_tx \_pmos )$$

$$V 319 M = VDD * ( Rtx + Ron\_tx \_nmos ) / ( Rrx + Ron\_tx \_nmos + Rtx + Ron\_rx \_pmos )$$

wherein,
V319P is the voltage at node 319P,
V319M is the voltage at node 319M,
Rrx is the resistance of each of resistor 321P and resistor 321M,
Rtx is the resistance of each of resistors 312P, 312M, 316P and 316M,
Ron_rx_nmos is the ON resistance of each of the NMOS transistors in inverters 320P and 320M,
Ron_rx_pmos is the ON resistance of each of the PMOS transistors in inverters 320P and 320M,
Ron_tx_nmos is the ON resistance of each of the NMOS transistors 310M and 315M, and
Ron_tx_pmos is the ON resistance of each of the PMOS transistors 310P and 315P.

Typically, the values of Ron_rx_nmos and Ron_rx_pmos are equal, and the values of Ron_tx_nmos and Ron_tx_nmos are equal. However, they can also be implemented to be different if so desired.

When the logic level across 319P and 319M is a logic low (negative voltage between nodes 319P and 319M), the voltages V319P and V319M are reversed.

The differential output signals of Tx 115A on paths 319P and 319M pass through signal distributor 120 and are shown connected to receiver 125A, signal distributor 120 being controlled to connect input port IA to output port OA (FIG. 1). For ease of description, the corresponding input and output ports of signal distributor 120 connected by the channel 319P/319M are not shown in FIG. 3. All the other transmitters of FIG. 1 are implemented similar to transmitter 115A, and are powered by the same magnitude of supply voltage Vd, although a separate power supply such as low-drop out (LDO) regulator is used for each transmitter.

Differential receiver 125A is shown containing a pair of self-biased inverters, a pair of back-to-back connected inverters (390P and 390M), a pair of inverters (330P and 330M) and a pair of inverting buffers (340P and 340M). The other receivers 125 of FIG. 1 are implemented similar to receiver 125A. The combination of inverter 320P and resistor 321P represents one self-biased inverter of receiver 125A, while the combination of inverter 320M and resistor 321M represents the other self-biased inverter. The input terminals of the two self-biased inverters are respectively connected to paths 319P and 319M. Each of inverters 320P, 320M, 390P, 390M, 330P and 330M is powered by supply voltage Vd (361). Inverting buffers 340P and 340M are each powered by supply voltage 371.

All the other receivers 125 of FIG. 1 are implemented similar to receiver 125A. All circuits of a receiver 125 are powered by a supply voltage equal to Vd, generated by a separate power supply such as another LDO, except that the pair of inverting buffers of the receiver are powered by a supply voltage Vd but generated by a separate power supply such as another LDO.

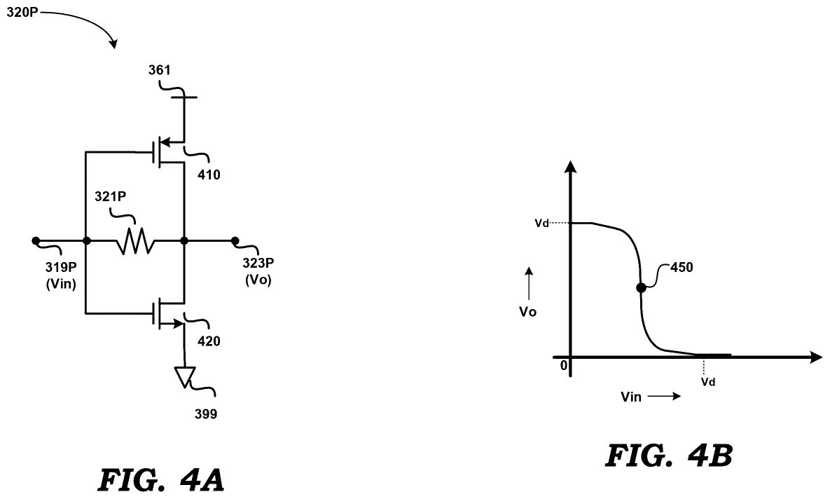

FIG. 4A is a circuit diagram illustrating the implementation of the self-biased inverters in receivers 125. Self-biased inverter 320P of FIG. 3 is shown in FIG. 4A containing PMOS 410, NMOS 420 and feedback resistor 321P. PMOS 410 and NMOS 420 are matched transistors and form an inverter. Resistor 321P is connected between the output terminal 323P (Vo) of the inverter and the input terminal 319P (Vin) of the inverter, and is implemented to have a sufficiently large resistance (e.g., 350 ohms). As is well known in the relevant arts, the feedback resistor (e.g., 321P) causes the self-biased inverter to be biased at a bias-point (DC-level) that is located at a high-gain region of the voltage-output to voltage-input relation of the self-biased inverter, as shown in FIG. 4B.

In FIG. 4B, magnitude of the input voltage Vin at node 319P is shown along the X axis, while magnitude of the output voltage Vo at node 323P is shown along the Y axis. The feedback resistor causes the bias-point (marked as 450) to be approximately mid-way between Vd (361) and ground, i.e., at Vd/2, since the transistors 410 and 420 are matched. The range of voltages for Vin and Vo in the output-input plot of FIG. 4A is 0 to Vd volts.

Due to the bias point being located at a region where the gain (Vo/Vin) is very high, even small variations in Vin about the bias voltage result in large voltage swings in Vo, as may be verified from an observation of the transfer curve of FIG. 4B. As a result, the signal at 319P can be a low-swing, i.e., low-amplitude signal, and still can reliably cause rail-to rail (Vd to 0 volts and vice-versa) swings in the corresponding output signal at 323P. Thus, a very small differential voltage swing (e.g., from +700 mV to −700mV) results in a large swing (from +Vd to −Vd) at the receiver output. Such a capability allows the transmitted signal (i.e., the signal at differential node-pair 319P/319M) to be a non-square wave signal, and yet generate a large voltage-swing (+/−Vd) at the output of the receiver. Such capability is useful especially at higher frequencies at which a square wave can undergo distortion due to attenuation of higher harmonics. As a result, the transmitted signal across nodes 319P/319M, and therefore through the signal distributor 120, can be made very small, thereby minimizing cross-talk, while still reliably receiving the signal at the receiver.

Receiver 125A presents a differential load-impedance (Zl) that is greater than the characteristic impedance (Zo) of the transmission channel between Rx 125A and Tx 125A. As is well known in the relevant arts, differential impedance is the ratio (V/I) of the voltage (V) and the current drawn (I) for differential excitation. Zl is resistive and is set by the resistance of the feedback resistors of the self-biased inverters of receiver 125A. With Zl implemented to be large (2Zo, in an embodiment), the signal strength/amplitude of the clock signal driven by a transmitter (such as 115A) is made sufficiently small, thereby reducing the probability and/or extent of cross-talk in the transmission channel (the path from the output of the transmitter to the input of the corresponding receiver, and through signal distributor 120) introduced by the clock signal. Even with any additional amplitude-reduction as the clock signal travels through the transmission channel due to channel impedance Zo, the high gain provided by receiver 125A due to the self-biased inverters ensures that the clock is reliably received and amplified without errors.

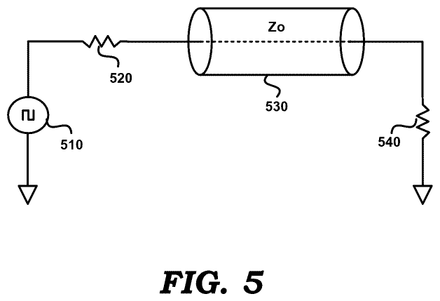

FIG. 5 is a diagram depicting the source impedance, transmission channel impedance and the load impedance for a single-ended circuit, and is provided to clarify the terms source impedance, characteristic impedance and load impedance. Component 510 represents a signal generator (and associated transmitter) and corresponds to any (e.g. signal generator 110A) of the signal generators of FIG. 1. Resistor 520 represents the source impedance of signal generator 510 and corresponds to the differential source impedance (2 R) of transmitter 115A. Zo represents the characteristic impedance of the single-ended transmission path 530, and corresponds to the differential impedance (characteristic impedance) of a transmission channel from a transmitter to a corresponding receiver in IC 100 (and which includes the corresponding differential path in signal distributor 120 also). Resistor 540 represents the impedance of the load in FIG. 5, and corresponds to the differential input impedance presented by a receiver (such as receiver 125A) in IC 100.

It is noted here that since the differential output impedance (also referred to herein as “source impedance Zs”, which may be set to, for example, Zo/2 in an embodiment) of a differential transmitter in IC 100 and the load impedance (e.g., 2Zo in the embodiment) of a differential receiver in IC 100 are not equal to the characteristic impedance Zo of the transmission channel, a clock signal transmitted from the transmitter to the receiver will exhibit ringing at signal level-transitions due to reflections caused by the impedance mismatches. While the choice of a small Zs generally reduces cross-talk, it can also lead to ringing and poorer signal integrity. The inventors have found that setting the value Zl to 2Zo (two times Zo) is an optimal setting that brings the benefit of reduced cross-talk while not significantly increasing signal degradation. Further, the use of self-biased inverters in the receiver converts a low-swing, potentially noisy clock signal at its inputs to clean rail-to-rail swing output clock signals.

The pair of back-to-back connected inverters (cross-coupled inverters) 390P and 390M operates as a duty-cycle corrector for the differential clock signal by aligning the positive and negative edges of the differential pair if they are not aligned, for example, due to unequal trace lengths of the pair of differential signal traces. The cross-coupled inverters also reduce or reject common-mode noise that might be induced in the clock signal at instants when the clock switches state, for example due to cross-talk from another clock signal. Both of the above benefits are obtained irrespective of PVT variations. As a result, unwanted spurs or phase-noise in the spectrum of the clock signal are either prevented or reduced in amplitude.

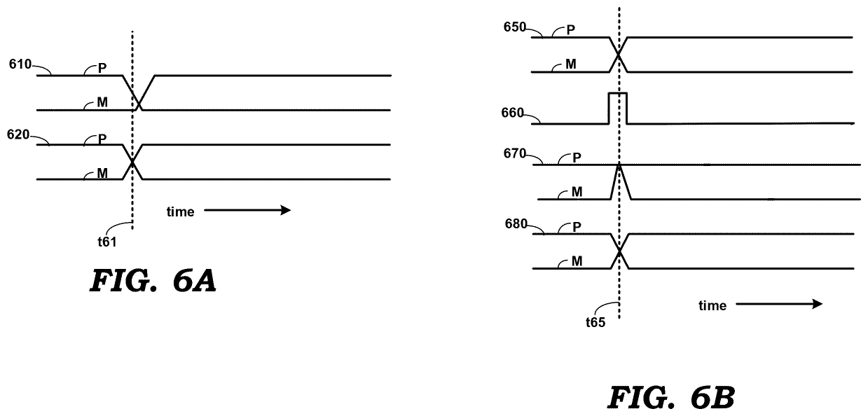

FIG. 6A is a diagram illustrating the duty-cycle correction of a differential signal. Waveform 610 represents a differential clock signal at the inputs of receiver 125A shown in FIG. 3. The positive and negative components of differential signal 610 are labelled as P and M respectively. The clock signal switches state at t61. However, due to unequal trace lengths of the two signal traces that the clock signal passes through, the P component is shown switching at t61 in FIG. 6A, while the M component switches slightly later than t61. Such non-simultaneous change in states manifests as phase noise in the spectrum of the clock signal, which is undesirable. The cross-coupled inverters align the level-transitions of the positive and negative signals of the differential pair. When the P component at node 323P switches at t61, inverter 390P forces the M component at node 323M to switch in the opposite sense, thereby aligning the switching instants, as indicated by the clock signal waveform 620 after alignment. If the switching were to occur earlier in the M component than in the P component, inverter 390M would operate in a similar manner to align the switching instants.

FIG. 6B is a diagram illustrating the manner in which the cross-coupled inverters reduce or remove the effect of cross-talk on the clock signal received at receiver 125A. As is well known in the relevant arts, cross-talk occurs due to electrical or magnetic coupling between a pair of signals. Cross-talk typically manifests as common-mode noise in a differential signal such as a clock signal noted herein. In FIG. 6B, waveform 650 represents a clock signal transmitted by transmitter 115A to receiver 125A. At t65, a level-switch of the clock occurs with both the components of the clock switching simultaneously. Waveform 660 represents noise due to cross-talk. The noise is shown to be zero except at (or about) time t65 when it is shown as a pulse. The pulse affects clock signal 650 as common-mode noise and induces equals voltages on both the positive and negative signal components of clock 650. The noise pulse speeds the level-change of the M component and delays that of the P component. The resulting clock waveform is indicated by numeral 670 in FIG. 6B. The non-simultaneous level-change at or about time t65 of the P and M components of the clock signal represented by 670 would manifest as phase noise unless corrected. In a manner similar to that described above with respect to FIG. 6A, the cross-coupled inverters operate to re-align the switching instants of the two components, thereby removing the effects of cross-talk, as indicated in the waveform of the ‘corrected’ or ‘re-aligned’ clock 680, which is similar to ‘original’ clock 650.

Referring again to FIG. 3, inverters 330P and 330M of receiver 125A are used for inverting the logic levels of the clock signal at nodes 323P and 323M respectively. Inverting buffers 340P and 340M receive the respective outputs of inverters 330P and 330M, and forward the logical inverse of the respective received signals with increased drive strength to output driver 350. Output driver 350 provides further drive strength and forwards the buffered clock signal to output pins 140D−/140D+.

The other transmitters and receivers of FIG. 1 are implemented similar to those shown in FIG. 3.

According to an aspect of the present disclosure, transmitters 115 and receivers 125 are designed and implemented in a manner that obviates the need for coupling capacitors between a transmitter-receiver pair, and also provides several benefits as described next.

### 4. Equal Common-Mode Levels

According to an aspect of the present disclosure, transmitters 115 and receivers 125 are designed to have the same common-mode (voltage) levels. As is well known in the relevant arts, common-mode level (voltage) in a differential circuit or path refers to the DC voltage level that is common to both the halves of the differential circuit/path, each half being the portion that generates or contains one of the pair of differential signals in the circuit. Common-mode level equals half the sum of the voltages on the differential paths (at all times of operation).

It may be observed that the transmitter-receiver pair shown in FIG. 3, namely Tx 115A and Rx 125A are powered by the same supply voltage magnitude (Vd). Firstly, the DC-level or bias point of each of the self-biased inverters is approximately Vd/2. Secondly, due to the matching of the PMOS and NMOS transistors of Tx 115A, and equal values of resistance (R) for all the resistors R1, R2, R3 and R4, the DC-level of each half of differential inverter/driver 115A is also Vd/2. As a result, the common-mode voltages of both Tx 115A and Rx 125A are equal.

Further, all the components of Tx 115A and Rx 125A are fabricated using the same process and on the same semiconductor die. Therefore, the transistors and resistors at either ends (transmitter and receiver) are matched, and any variations in their parameters over process, voltage and temperature (PVT) are substantially identical. Hence, the common-mode level of both the transmitters and receivers do not differ (at least substantially) with variations in PVT.

With the same common-mode voltage level in all the transmitters and receivers, a transmitter can be directly connected (with or without an intervening signal distributor channel) to a receiver without the need for AC coupling capacitors between the two. Thus, Tx 115A and Rx 125A are shown connected (via signal distributor 120) without any coupling capacitors being provided between them. Had the common-mode voltages been different, then coupling capacitors are required in the connecting path between a transmitter and a receiver to prevent the common-mode voltage of one from affecting the operation of the other and/or ensuring reliable receipt at the receiver of the transmitted differential signal.

Due to the direct connection between transmitter and receiver without any coupling capacitors there is no lower limit on the frequency that the clock signals can have. In an embodiment, the range of frequencies of the clock signals for which the signal generators are designed ranges from 1 Hz to 2 GHz. There is no penalty in terms of implementation area in IC 100 that would otherwise have been needed for the coupling capacitors.

Another benefit is that the clock signals do not suffer amplitude reduction that would

result with having to pass through coupling capacitors, which may be associated with some series resistance due to their construction. Further, when implemented on-chip, a capacitor may be associated with parasitic capacitances to ground, which can further result in amplitude loss in the clock signals. Further, there are no transients (e.g., glitches in logic levels) in the clock signals at the output pins immediately following power-up, as would occur if coupling capacitors were used. Such transients could manifest for a few clock cycles following power-up when the coupling capacitors charge to their steady-state average charge corresponding to the clock signal's frequency.

When the components and blocks of FIG. 1 are implemented as single-ended circuits and paths, the ‘DC-levels’ (the voltage value around which the signal varies) at the output of a transmitter and input of a receiver are equal (Vd/2), and again coupling capacitors are not required to be used. The term ‘DC operating-point’ is used herein to refer to both a common-mode level of a differential circuit/path, as well as a DC-level of a single-ended circuit/path.

According to another aspect of the present disclosure, a transmitter can be controlled to select one of multiple amplitudes with which to drive a clock signal, and is described next.

### 5. Controllable Transmit Amplitude

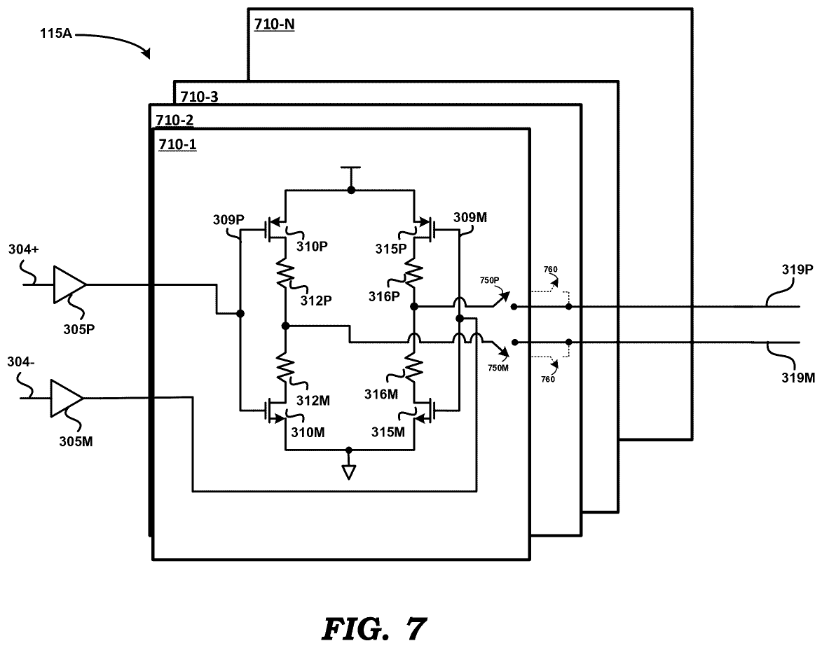

FIG. 7 is a diagram illustrating the implementation of a transmitter in an embodiment of the present disclosure. Transmitter 115A of FIG. 1 is shown there as containing multiple instances (slices) of SST (source-series terminated) differential drivers 710-1 through 710-N, with a desired number of slices operable to be connected in parallel with each other. In an embodiment, N equals four, although N can be larger or smaller than four.

Each SST driver (transmit slice) is similar or identical to the SST driver shown in FIG. 3, in which only one slice or instance of a driver is shown. Slice 710-1 is shown to be identical to SST driver 115A shown in FIG. 3, with the addition of switches 750P and 750M. Each of the other slices 710-2, 710-3, etc., also have switches operable to connect and disconnect the slice's output to common path 319P/319M. Optionally, the inputs of each of the slices can be also have switches to connect and disconnect the slice to the output of clock generator 110A (via the output terminals of buffers 305P and 305M.

Switches 760P and 760M of slice 710-2 are also shown in FIG. 7, while the switches of the other slices are not shown. Switches 750P/750M, 760P/760M and those (not shown) of the other slices are controllable to be closed or open in a known way, for example, by user input or configuration from an external device, on-chip configuration memory, etc. The clock output by clock generator 110A is received in differential form on paths 304+/304− and buffered by buffers 305P and 305M. The respective outputs of buffers 305P and 305M are connected to the corresponding input nodes of each of the SST driver slices. The connection to inputs nodes 309P and 309M of slice 710-1 are shown in FIG. 7.

Depending on the amplitude desired for the clock signal transmitted on the outputs 319P/319M, the corresponding number of switches of the slices are closed, thereby connecting the outputs of only those slices to the output path 319P/319M. If a lower amplitude is desired for the clock signal driven on path 319P/319M then fewer slices are used. For example, only one slice may be used for the lowest amplitude. If higher amplitudes are desired, then as many slices are used to drive the clock signal on path 319P/319M as needed. As the number of slices simultaneously driving the output 319P/319M increases, the effective source impedance decreases and the amplitude of the driven clock signal is correspondingly higher for the same load impedance offered by receiver 125A. As noted above, lower amplitudes can improve cross-talk performance by reducing electrical or magnetic coupling to other clock signal traces.

It is noted here that an SST driver such as those described herein is associated with lower noise as compare to other types of drivers, such as current-mode logic (CML) drivers with a tail current source. Further, SST drivers cause negligible degradation of flat-band noise (e.g., offset 10 MH from the carrier frequency) in the spectrum of the driven clock signals. Further still, SST drivers are associated with smaller parasitic capacitances, and therefore can support higher clock frequencies.

According to another aspect of the present disclosure, separate power supplies are employed for different circuit sections in the clock signal path from a signal generator/transmitter to output pin of IC 100, as described next.

### 6. Supply Partitioning

Referring to FIG. 3 again, separate power supplies are shown there as being used for powering different sections of the signal path there from transmitter 115A to output pins 140D+/140D−. Three low-dropout regulators (LDO) 360, 370 and 380 are shown in FIG. 3, each receiving power from a power source Vs (301, external to IC 100) and generating regulated supply voltages on outputs 361, 371 and 381 respectively. Supply voltage 361 (Vd) is used for powering transmitter 115A (all or only the desired number of slices as shown in FIG. 7) and receiver 125A. Supply voltage 371 is used for powering inverting buffers 340P and 340M. Supply voltage 381 is used for powering output driver (DRV) 350, which further buffers the clock signal onto output pins 140D+/140D−. Although not shown, another power supply is used for powering the PLL circuitry of clock generator 110A. Each of the other transmitter-receiver-driver sets are powered by another set of three LDOs in a manner similar to that shown in FIG. 3.

Each of inverting buffers 340P/340M and output driver 350 are associated with large capacitances at their respective outputs, and are associated with larger switching currents than Tx 115A and/or Rx 125A. The currents drawn by each of Tx 115A and Rx 125A are relatively smaller and less noisy. Hence, the supply voltages 371 and 381 may exhibit greater noise or ripple than supply voltage 361. The use of separate power supplies for Tx 115A/Rx 1125A, buffers 340P/340M and output driver 350 ensures that the supply noise (e.g., due to switching currents) in LDO 370 and/or LDO 380 are not coupled into the electrical channel between a clock generator and the corresponding IC output pins. Therefore, very good isolation between or among the various electrical channels is achieved and cross-talk is low.

The various techniques described above enable reduction of cross-talk when multiple signals are to be routed in close proximity.

IC 100 implemented as described above can be incorporated in a larger system. The details of one such example system are described next.

### 7. System

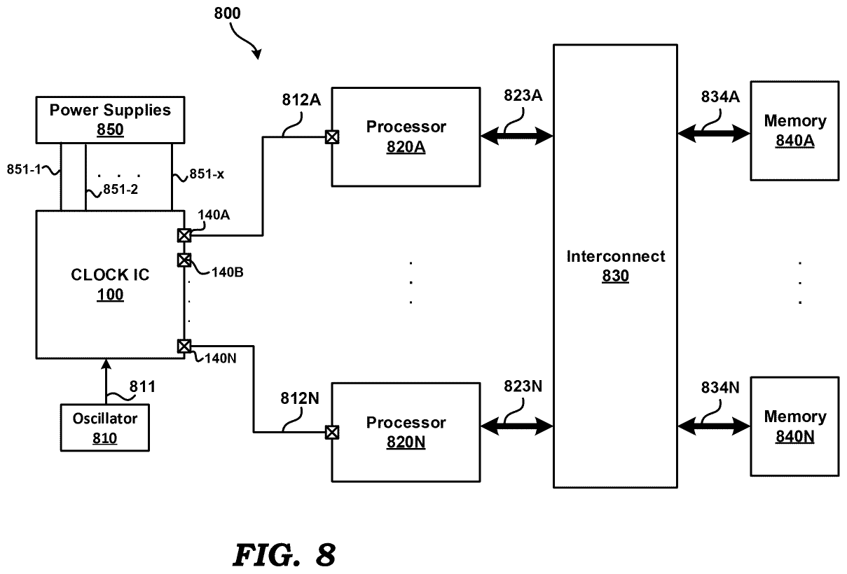

FIG. 8 is a diagram illustrating the details of a system in an embodiment of the present disclosure. Multiprocessor system 800 is shown there containing clock IC 100, oscillator 810, processors 820-820N, interconnect 830, memories 840A-840-N and power supplies 850. The components of multiprocessor system 800 may be assembled on a printed circuit board (PCB). System 800 would typically contain more components and blocks, which are not shown in the interest of simplicity and conciseness, but which would be apparent to one skilled in the relevant arts.

Each of processors 820A-820N represents one or more processing units (or cores) that can execute instructions and operate on data to provide one or more desired functions. The processors retrieve the instructions and store/fetch data from one or more of memories 840A-840N via interconnect 830.

Memories 840A-840N (memory units) represent a combination of volatile and non-volatile memory, and are used to store instructions and data for use by one or more of processors 820A-820N.

Interconnect 830 provides electrical paths for connecting the processors 840A-840N with memories 840A-840N, and may be implemented in a known way and according to interconnect standards. Processors 820A-820N are respectively connected to interconnect 830 on respective paths 832A-823N. Memories 840A-840N are respectively connected to interconnect 830 on respective paths 834A-834N. Interconnect 830 is designed to permit transfer of instructions and data between any of processors 820A-820N and any of memory units 840A-820N in a known way.

Each of processors 820A-820N receives a respective clock from clock IC 100 and operates based on the received clock, which serves a timing reference for coordinating the operations of the corresponding processor.

Power supplies 850 includes multiple voltage regulators (such as LDOs) and provides separate power supply voltages for the various sections/blocks within clock IC 100 as noted above. Oscillator 810 provides a reference clock on path 811 for use by the PLLs in clock IC 100 for generating clock signals.

Clock IC 100 is the same as shown and described in FIG. 1 (and other figures) above, and operates to generate multiple clock signals on pins 140A-140N. The respective clock signals are provided on respective paths 812A-812N to processors 820A-820N respectively. Paths 812A-812N terminate on respective clock input terminals of the respective processors 820A-820N. Clock IC 100 is implemented as described in detail above, and generates clock signals and distributes them to the pins 140A-140N with minimal cross-talk by employing the techniques described herein.

### 8. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1 through 8, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A circuit comprising:
a plurality of signal traces, each signal trace having a corresponding input end and a corresponding output end, each signal trace to propagate a corresponding signal received at the corresponding input end to the corresponding output end;
a plurality of transmitters, with an output of each transmitter being coupled to a corresponding input end of a respective signal trace; and
a plurality of receivers, with an input of each receiver being coupled to a corresponding output end of a respective signal trace,
wherein each receiver comprises a self-biased inverter biased in a high-gain region,
wherein a DC operating-point of each transmitter equals that of the corresponding receiver.

2. The circuit of claim 1, further comprising:
a plurality of signal generators, each signal generator to generate said corresponding input signal; and
a signal distributor having a plurality of input ports and a plurality of output ports, each input port constituting said input end and each output port constituting said output end,
said signal distributor operable to couple any input port of said plurality of input ports to any output port of said plurality of output ports.

3. The circuit of claim 1, wherein said self-biased inverter comprises:
an inverter having an input node and an output node; and
a resistor coupled in parallel to said inverter between said input node and said output node.

4. The circuit of claim 3, wherein said corresponding signal is a differential signal and said DC operating-point equals a common-mode level of said differential signal.

5. The circuit of claim 4, wherein each of said plurality of transmitters comprises a differential transmitter, each of said plurality of receivers comprises a differential receiver and each of said plurality of signal traces comprises differential traces.

6. The circuit of claim 5, wherein each transmitter comprises a source-series terminated (SST) inverter.

7. The circuit of claim 6, wherein each transmitter comprises a plurality of transmit slices, each operable to be controllably coupled to said corresponding input end of a respective signal trace.

8. The circuit of claim 7, wherein a differential load-impedance presented by each receiver in said plurality of receivers is greater than a characteristic impedance of the corresponding signal trace.

9. The circuit of claim 8, wherein a differential source-impedance of each transmitter in said plurality of transmitters is less than said characteristic impedance of the corresponding signal trace.

10. The circuit of claim 9, wherein each receiver further comprises a pair of cross-coupled inverters coupled between respective output nodes of the corresponding self-biased inverters of the receiver.

11. The circuit of claim 10, wherein each receiver further comprises a pair of inverting buffers, wherein a first inverting buffer of said pair is coupled to a first output node of said respective output nodes of the corresponding self-biased inverters, and a second inverting buffer of said pair is coupled to a second output node of said respective output nodes of the corresponding self-biased inverters.

12. The circuit of claim 11, wherein a pair of self-biased inverters of a first receiver of said plurality of receivers is powered by a first power supply,
wherein a first pair of inverting buffers of said first receiver is powered by a second power supply.

13. The circuit of claim 12, wherein said signal distributor couples a first transmitter of said plurality of transmitters to said first receiver, wherein said first transmitter is also powered by said first power supply.

14. The circuit of claim 13, further comprising a plurality of differential drivers, each differential driver coupled to an output of a pair of inverting buffers of a corresponding receiver, a first differential driver being coupled to an output of said first pair of inverting buffers,
wherein said first differential driver is powered by a third power supply.

15. A system comprising:
a plurality of processors for executing instructions;
a plurality of memory units for storing instructions and data;
an interconnect to couple said processors to said memory units; and
a clock integrated circuit (IC) to generate a plurality of clock signals, wherein a respective clock signal of said plurality of clock signals is coupled to a clock input of a respective one of said plurality of processors, said respective clock signal serving as a timing reference to coordinate the operations of said respective processor,
wherein said clock IC comprises:
a plurality of signal traces, each signal trace having a corresponding input end and a corresponding output end, each signal trace to propagate said respective clock signal received at the corresponding input end to the corresponding output end;
a plurality of transmitters, with an output of each transmitter being coupled to a corresponding input end of a respective signal trace; and
a plurality of receivers, with an input of each receiver being coupled to a corresponding output end of a respective signal trace,
wherein each receiver comprises a self-biased inverter biased in a high-gain region,
wherein a DC operating-point of each transmitter equals that of the corresponding receiver.

16. The system of claim 15, wherein said clock IC further comprises:
a plurality of phase locked loops (PLL), each PLL to generate said respective clock signal; and
a signal distributor having a plurality of input ports and a plurality of output ports, each input port constituting said input end and each output port constituting said output end,
said signal distributor operable to couple any input port of said plurality of input ports to any output port of said plurality of output ports.

17. The system of claim 16, wherein said self-biased inverter comprises:
an inverter having an input node and an output node; and
a resistor coupled in parallel to said inverter between said input node and said output node.

18. The system of claim 17, wherein said respective clock signal is a differential signal and said DC operating-point equals a common-mode level of said differential signal.

19. The system of claim 18, wherein each receiver further comprises:
a pair of cross-coupled inverters coupled between respective output nodes of the self-biased inverters of the receiver; and
a pair of inverting buffers, wherein a first inverting buffer of said pair is coupled to a first output node of said respective output nodes of the self-biased inverters, and a second inverting buffer of said pair is coupled to a second output node of said respective output nodes of the self-biased inverters.

20. The system of claim 19, further comprising a plurality of voltage regulators,
wherein a pair of self-biased inverters of a first receiver of said plurality of receivers is powered by a first voltage regulator,
wherein a first pair of inverting buffers of said first receiver is powered by a second power supply,
wherein said signal distributor couples a first transmitter of said plurality of transmitters to said first receiver,
wherein said first transmitter is also powered by said first voltage regulator.
